(19) United States
(12) Patent Application Publication
(10) Pub. No.: US 2015/0111373 A1
(43) Pub. Date: Apr. 23, 2015

(54) REDUCING GATE HEIGHT VARIATION IN RMG PROCESS

(71) Applicants: GLOBALFOUNDRIES, INC.; International Business Machines Corporation, Armonk, NY (US)

(72) Inventors: William J. Cote, Poughquag, NY (US); Laertis Economikos, Wappingers Falls, NY (US); Shom Ponoth, Gaithersburg, MD (US); Theodorus E. Standaert, Clifton Park, NY (US); Charan V. Surisetty, Clifton Park, NY (US); Ruilong Xie, Niskayuna, NY (US)

(73) Assignees: GLOBALFOUNDRIES, INC.; International Business Machines Corporation, Armonk, NY (US)

(21) Appl. No.: 14/057,357

(22) Filed: Oct. 18, 2013

(51) Int. Cl. H01L 21/8238; H01L 21/8234

(52) U.S. Cl. CPC H01L 21/823828; H01L 21/823468; H01L 21/823437; H01L 21/823864
USPC 438/586; 438/595

(57) ABSTRACT

A method of forming transistors is provided. The method includes forming a plurality of transistor structures to have a plurality of dummy gates on a substrate. Each dummy gate is surrounded by sidewall spacers of a height, which is less than the dummy gate and is different for different transistor structures resulting in divots of different depths above the sidewall spacers. The method then deposits a conformal dielectric layer on top of the dummy gates and inside the divots of the plurality of transistor structures with the conformal dielectric layer having a thickness of at least half of a width of the divots, removes only a portion of the conformal dielectric layer that is on top of the dummy gates to expose the dummy gates; and replaces the dummy gates with a plurality of high-k metal gates.

### FIELD OF THE INVENTION

The present invention relates generally to the manufacturing of semiconductor devices and, in particular, to the manufacturing of transistors in a replacement-metal-gate process.

### BACKGROUND

In the field of semiconductor device manufacturing, active semiconductor devices such as, for example, transistors are manufactured through processes commonly known as front end of line (FEOL) technologies or processes. A transistor may be, for example, a field-effect-transistor (FET) and more specifically may be a complementary metal-oxide-semiconductor FET (CMOS-FET). A FET may additionally be a p-type dopant doped FET (pFET), or an n-type dopant doped FET (nFET).

Recently, semiconductor transistors made with high-k metal gate (HKMG) have started to be widely adopted because of their superior performance over conventional or traditional poly-silicon based transistors. In addition, new processes, such as a replacement metal gate (RMG) process, have been developed for the manufacturing of HKMG transistors for improved manufacturability and ease of integration with other advanced device features.

Nevertheless, in association with the RMG process, there is process variation relating to a step or steps of forming nitride hard-mask over dummy gates of transistors and in particular over dummy gates of transistors that are separated in relatively large distances across a substrate or wafer. More specifically, the process variation causes a variation in the thickness of the nitride hard-mask, which may eventually lead to gate height variation and result in noticeable performance variation among the concerned transistors, all of which depend on where on the substrate or wafer that the transistor is manufactured when the current conventional RMG process of manufacturing is used.

### SUMMARY

Embodiment of the present invention provides a method of forming semiconductor transistors with replacement-metal-gate. The method includes forming a first and a second gate structure on a same substrate, the first and second gate structures having respectively a first and a second dummy gate of a substantially same height and being covered by a first and a second hard mask of different thicknesses; removing the first and second hard masks from the first and second dummy gates, the removing etches top portions of a first and a second set of sidewall spacers that are adjacent to the first and second dummy gates respectively and are embedded inside one or more dielectric layers, thereby causing divots of different depths above the first and second set of sidewall spacers surrounded by the one or more dielectric layers; depositing a conformal dielectric layer on top of the first and second dummy gates and inside the divots, the conformal dielectric layer being sufficiently thick to fill up the divots; removing portions of the conformal dielectric layer to expose the first and second dummy gates underneath thereof; and replacing the first and second dummy gates with a first and a second high-k metal gates.

According to one embodiment, removing portions of the conformal dielectric layer includes isotropically etching a first portion of the conformal dielectric layer on top of the first and second dummy gates without affecting a second portion of the conformal dielectric layer that is deposited inside the divots.

According to another embodiment, the method further includes planarizing the one or more dielectric layers surrounding the first and second gate structures using the first and second dummy gates as etch-stop.

According to one embodiment, replacing the first and second dummy gates includes selectively removing the first and second dummy gates to expose the substrate underneath thereof and the first and second set of sidewall spacers, thereby creating gate openings; and filling gate openings with work-function metal and conductive material to form the first and second high-k metal gates.

According to another embodiment, the method further includes creating recesses in the first and second high-k metal gates and filling the recesses with a nitride cap layer.

According to one embodiment, depositing the conformal dielectric layer inside the divots includes depositing a hafnium-oxide material inside the divots around the corners of the first and second dummy gates above their respective first and second set of sidewall spacers.

According to another embodiment, the method further includes creating at least one contact opening inside the one or more dielectric layers through a selective etching process, the selective etching process being selective to the rest of the conformal dielectric layer inside the divots, and the contact opening being self aligned to the first and second set of sidewall spacers; and filling the contact opening with a conductive material to form a source/drain contact.

### BRIEF DESCRIPTION OF THE DRAWINGS

The present invention will be understood and appreciated more fully from the following detailed description of the invention, taken in conjunction with the accompanying drawings of which:

FIGS. 1a-1d are demonstrative illustrations of a method of forming transistors with replacement metal gate as is known in the art;

FIG. 2 is a demonstrative illustration of a method of forming transistors with replacement metal gate according to one embodiment of the present invention;

FIG. 3 is a demonstrative illustration of a method of forming transistors with replacement metal gate, following the step illustrated in FIG. 2, according to one embodiment of the present invention;

FIG. 4 is a demonstrative illustration of a method of forming transistors with replacement metal gate, following the step illustrated in FIG. 3, according to one embodiment of the present invention;

FIG. 5 is a demonstrative illustration of a method of forming transistors with replacement metal gate, following the step illustrated in FIG. 4, according to one embodiment of the present invention;

FIG. 6 is a demonstrative illustration of a method of forming transistors with replacement metal gate, following the step illustrated in FIG. 5, according to one embodiment of the present invention;

FIG. 7 is a demonstrative illustration of a method of forming transistors with replacement metal gate, following the step illustrated in FIG. 6, according to one embodiment of the present invention;

FIG. 8 is a demonstrative illustration of a method of forming transistors with replacement metal gate, following the step illustrated in FIG. 7, according to one embodiment of the present invention;

FIG. 9 is a demonstrative illustration of a method of forming transistors with replacement metal gate, following the step illustrated in FIG. 8, according to one embodiment of the present invention; and

FIG. 10 is a demonstrative illustration of a method of forming transistors with replacement metal gate, following the step illustrated in FIG. 9, according to one embodiment of the present invention.

It will be appreciated by a person skilled in the art that for simplicity reason and for clarity of illustration, elements shown in the drawings have not necessarily been drawn to scale. For example, dimensions of some of the elements may be exaggerated relative to other elements for clarity purpose.

### DETAILED DESCRIPTION OF PREFERRED EMBODIMENTS

In the following detailed description, numerous specific details are set forth in order to provide a thorough understanding of embodiments of the invention. However, it will be understood by those of ordinary skill in the art that embodiments of the invention may be practiced without these specific details. In other instances, well-known methods and procedures have not been described in detail so as not to obscure description of essences of embodiments of the invention.

In the following description, various figures, diagrams, flowcharts, models, and descriptions are presented as different means to effectively convey the substances and illustrate different embodiments of the invention that are proposed in this application. It shall be understood by those skilled in the art that they are provided merely as exemplary samples, and shall not be constructed as limitation to the invention.

In the below detailed description, some steps of the method may be illustratively shown by a series of cross-sectional views of the semiconductor devices under manufacturing. Some well known steps and/or processes may be intentionally omitted in order not to obscure description of essence of embodiment of present invention.

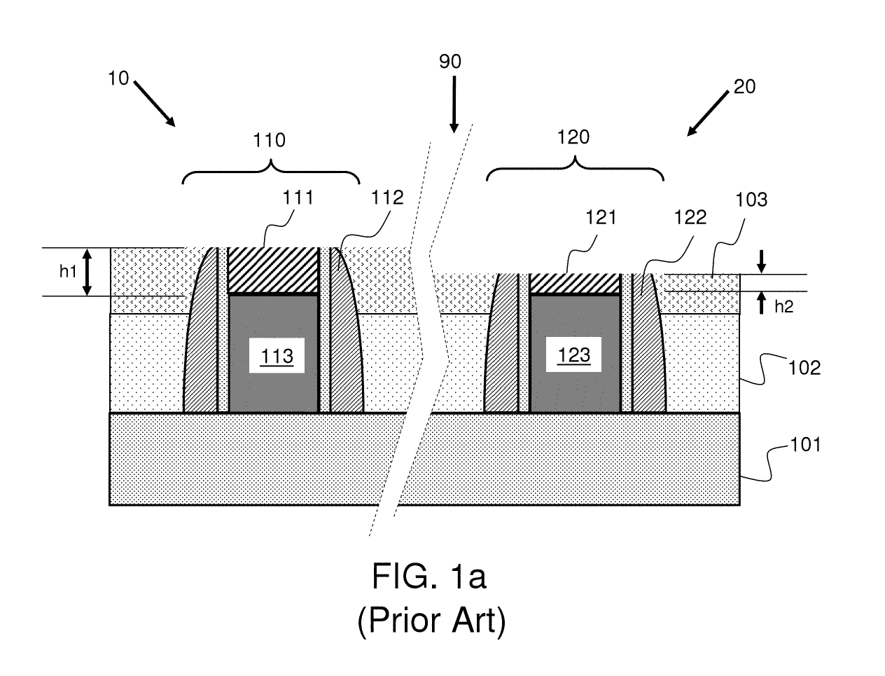

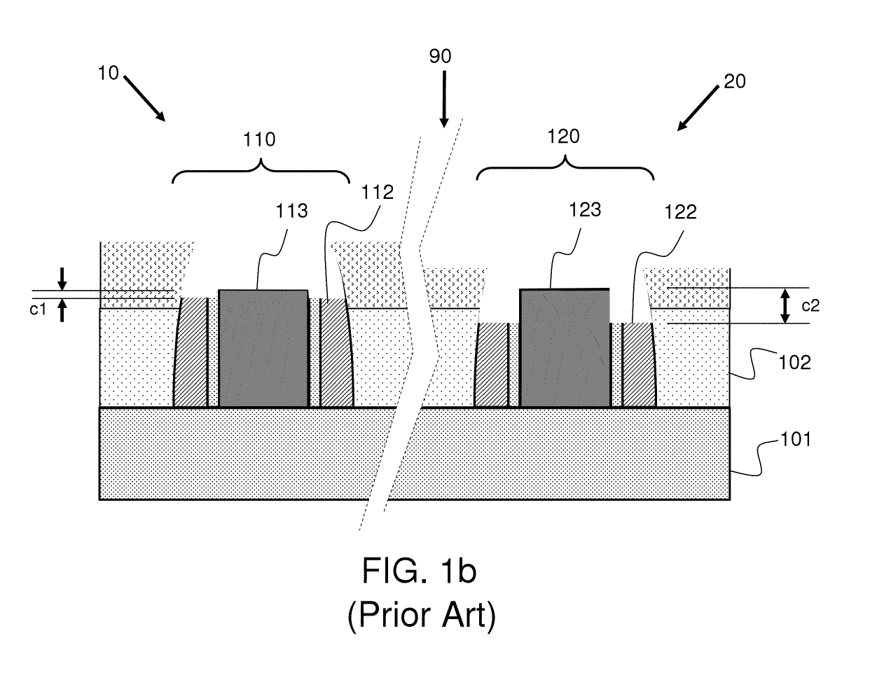

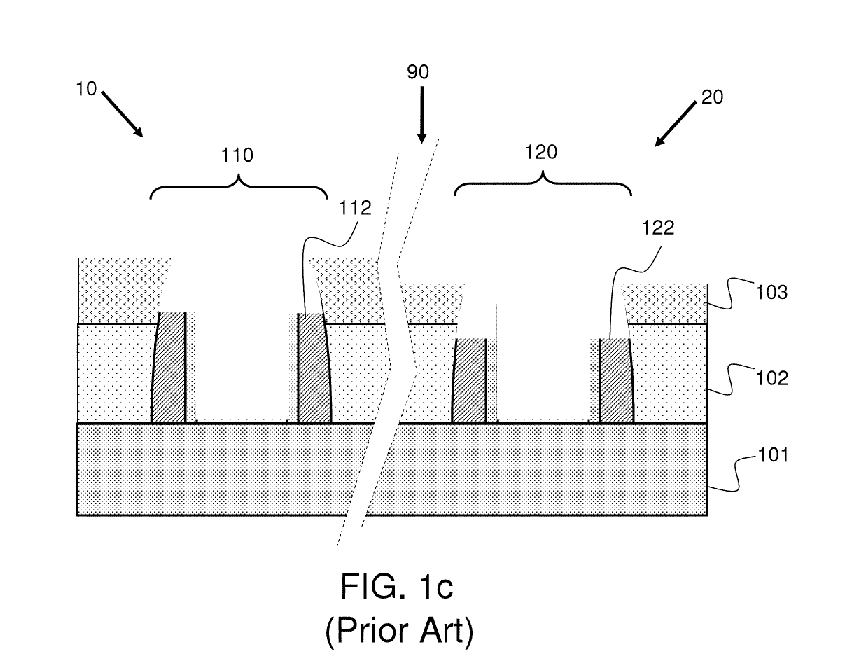

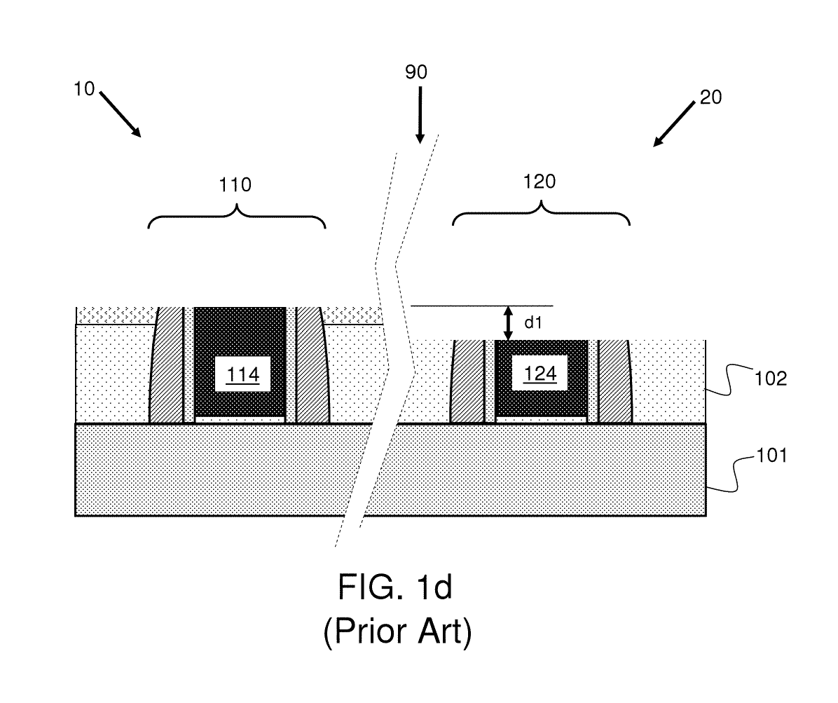

FIGS. 1a-1d are demonstrative illustrations of a method of forming transistors with replacement metal gate as is known in the art. More specifically, FIG. 1a demonstratively illustrates a typical step of a conventional method of forming multiple transistors, such as transistors 110 and 120, on a single substrate 101. Transistors 110 and 120 are assumed to be separated in a relatively large distance across single substrate 101. Here, “relatively large distance” refers to a situation where two or more transistors, such as transistors 110 and 120, are separated in such a way that nitride cap layers or nitride hard-masks 111 and 121 formed on top of dummy gates 113 and 123 exhibit a noticeable and sometimes even significant difference in thickness, as is known in the art and frequently observed in a step of current replacement-metal-gate (RMG) process. To represent this “relatively large distance”, transistors 110 and 120 are symbolically illustrated as being separated by symbol 90 in FIG. 1a-1d. The thickness variation in nitride hard-masks 111 and 121 may be caused by one or more reasons such as, for example, loading effect during a silicon-nitride (SiN) spacer formation process using reactive-ion-etching (RIE), and/or caused by non-uniformity of a chemical-mechanic-polishing (CMP) process when the CMP process is employed to polish the oxide inter-level-dielectric (ILD) layer above the gate to expose the underneath nitride cap or hard-mask.

As is demonstratively illustrated in FIG. 1a, transistors 110 and 120 may be formed, during a regular process of manufacturing thereof, to have poly-silicon (poly-Si) or amorphous-silicon (a-Si) dummy gates 113 and 123 covered on top thereof by nitride hard-masks or cap layers 111 and 121 respectively. Dummy gates 113 and 123, together with nitride cap layers 111 and 121 on top thereof, may be surrounded by one or more sidewall spacers 112 and 122. Dummy gates 113 and 123, nitride cap layers 111 and 121, and sidewall spacers 112 and 122, all of which may in-turn be embedded inside one or more dielectric layers 102 and 103 which may be inter-level-dielectric (ILD) layers of oxide or flow-able oxide. As being demonstratively illustrated in FIG. 1a, a top surface of the one or more dielectric layers 102 and 103, such as the top surface of dielectric layer 103, may be made co-planar with a top surface of nitride cap layers 111 and 121 during the manufacturing process.

Sidewall spacers 112 and 122 may each have a height equal to a combined total height of dummy gate 113 and nitride cap layer 111 on top thereof or dummy gate 123 and nitride cap layer 121 on top thereof, which sidewall spacers 112 and 122 are adjacent to respectively. However, because nitride cap layers 111 and 121 of different transistors 110 and 120 may have different thickness such as thickness h1 of nitride cap layer 111 and thickness h2 of nitride cap layer 121, their respective sidewall spacers may have different height as well.

As is illustrated in FIG. 1b, according to current conventional RMG process, a selective isotropic (or anisotropic) etching process may be applied to remove nitride cap layers 111 and 121 to expose the underneath dummy gates 113 and 123 in preparation for making replacement metal gate. The isotropic etching process may be selective to underneath dummy gates 113 and 123 but is non-selective to sidewall spacers that have similar etching properties as that of nitride cap layer. The removal of nitride cap layers 111 and 121 thus may partially etch into sidewall spacers 112 and 122. In order to completely remove the nitride cap layers of all the transistors, the etching process may be performed long enough such that nitride cap layer with the thickest thickness, for example nitride cap layer 111 of transistor 110 among all other transistors, may be removed. The removal of nitride cap layer 111 on top of dummy gate 113 maybe performed slightly longer than necessary in order to ensure a completely exposed top surface of dummy gate 113. The over-etch may thus cause sidewall spacers surrounding dummy metal gate 113 to have a small dip c1.

In the meantime, while nitride cap layer 111 on top of dummy gate 113 is removed, nitride cap layers on top of other transistors and sidewall spacers surrounding dummy gates of these transistors may be removed as well. For example, as being demonstratively illustrated in FIG. 1b, nitride cap layer 121 may be removed together with a portion of sidewall spacers 122. The total amount (in height) of sidewall spacers 122 that is removed may be similar to that of sidewall spacers 112, which may be same or slightly bigger than thickness of nitride cap layer 111. In other words, a bigger portion of sidewalls of dummy gate 123 may be exposed by the lowering of height of sidewall spacers 122, creating divots between dummy gate 123 and surrounding dielectric layers 102 and/or 103. For example, divots associated with transistor 120 may have a depth c2 that is noticeably or sometimes significantly deeper than that divot c1 associated with transistor 110. Depths of divots associated with different transistors may be different depending upon their respective heights of sidewall spacers at the beginning of the nitride cap layer removing process.

Next, as being demonstratively illustrated in FIG. 1c, the conventional replace-metal-gate process continues to selectively remove dummy gates 113 and 123 by, for example, applying a wet etching process such as using hot ammonia in a wet etching process. The removal process creates openings in the previous dummy gate regions.

After dummy gates 113 and 123 are removed, high-k metal gate stacks 114 and 124 may be deposited inside the created openings of replacement metal gate structure, as being demonstratively illustrated in FIG. 1d. The deposition of high-k metal gate material may be followed by a CMP planarization process. At this stage, it is generally difficult to achieve uniform gate height of high-k metal gates 114 and 124 because neither the thickness of ILD layers 102 and 103 nor the height of spacers 112 and 122 surrounding high-k metal gates 114 and 124 are uniform between transistors 110 and 120. Thus, as being illustrated in FIG. 1d, the CMP planarization process may have to bring the high-k metal gates of different transistors to the heights of their respective sidewall spacers, whose heights may be different caused by preceding nitride cap removal process. In other words, it becomes inevitable that various transistors on the same substrate 101 may have different gate height, such as a difference d1 as being illustrated in FIG. 1d, creating performance variations among all the transistors due to variation in gate height.

In recognizing the above, embodiments of present invention provide a method that helps reduce or eliminate gate height variation among transistor devices manufactured on a same substrate.

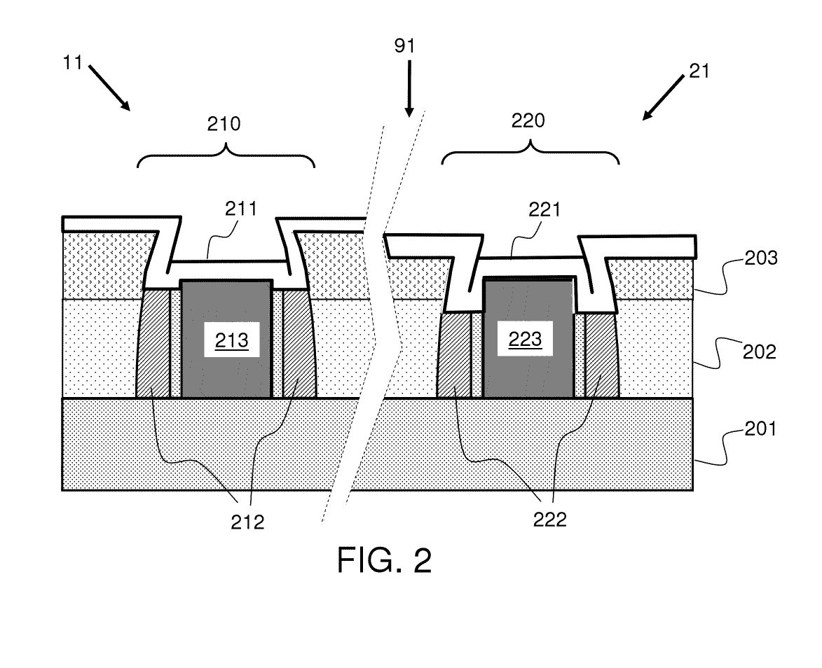

FIG. 2 is a demonstrative illustration of a method of forming transistors with replacement metal gate according to one embodiment of present invention. More specifically, FIG. 2 illustrates a step of forming a plurality of replacement-metal-gate transistors on a same substrate but the transistors are separated in relatively large distances and as a result they may be formed, due to process variation across wafer or substrate, to suffer different thicknesses of nitride cap layers on top of their respective dummy gates, which may be similar to those illustrated in FIG. 1a. Here in FIG. 2, in order to distinguish from current RMG process that is illustrated in FIG. 1a-1d, transistors 210 and 220 are illustrated to be manufactured on a substrate 201 in a first region 11 and a second region 21. At this stage, transistors 210 and 220 may respectively have their dummy gates 213 and 223 and surrounding sidewall spacers 212 and 222 embedded inside one or more dielectric layers 202 and 203.

After removing nitride cap layers on top of all the transistors in a step similar to that illustrated in FIG. 1b, one embodiment of present invention includes depositing a conformal dielectric layer to fill up divots that are above sidewall spacers between dummy gates and their surrounding dielectric layers. Divots above sidewall spacers 212 and 222 between dummy gate 213 (or 223) and the one or more dielectric layers 202 and/or 203 may have different depths and different widths. Some divots, in particular divots that were etched deep into sidewall spacers, may have a width that, at locations around the upper corners of the dummy gate, is slightly narrower due to the particular shape of sidewall spacer that was removed.

In FIG. 2, the deposited conformal dielectric layer may be illustrated as dielectric layer 211 in the first region 11 and dielectric layer 221 in the second region of substrate 201. It is to be noted that dielectric layers 211 and 221 are in fact a same dielectric layer deposited through a same deposition step or process, and different reference numbers 211 and 221 are used here purely for easy reference purpose. Dielectric layer 211 and 221 may be, for example, silicon-nitride (SiN) or hafnium-oxide (HfO₂) and in one embodiment may be made of a same material as underneath sidewall spacers. In one embodiment, dielectric layer 211 and 221 may have sufficient etch selectivity with respect to surrounding dielectric layers 202 and/or 203 which may be oxide or flow-able oxide. Hereinafter, dielectric layer 211 and 221 may sometimes be referred to as divot filling material.

According to one embodiment of present invention, the method may include depositing conformal dielectric layer 211 and 221 to have a thickness that is at least half of the width of the widest divot among all of the transistors under manufacturing. With the thickness being at least half of the width of the divots, conformal dielectric layers 211 and 221 may be deposited to completely fill up the divots as well as being formed on top of the respective dummy gates. In one embodiment, depending upon deposition condition, the deposition of dielectric layer 211 and 221 may leave a seam along the middle of the divot where the top surface of the deposited dielectric layer meet each other to finish filling up the divot. In another embodiment, when the divot has a slightly smaller opening at the location around an upper corner of the dummy gate, some level of void may be created inside the divot due to pinching off that may be surrounded by the deposited dielectric layer. Both seam and small void are acceptable according to embodiment of present invention.

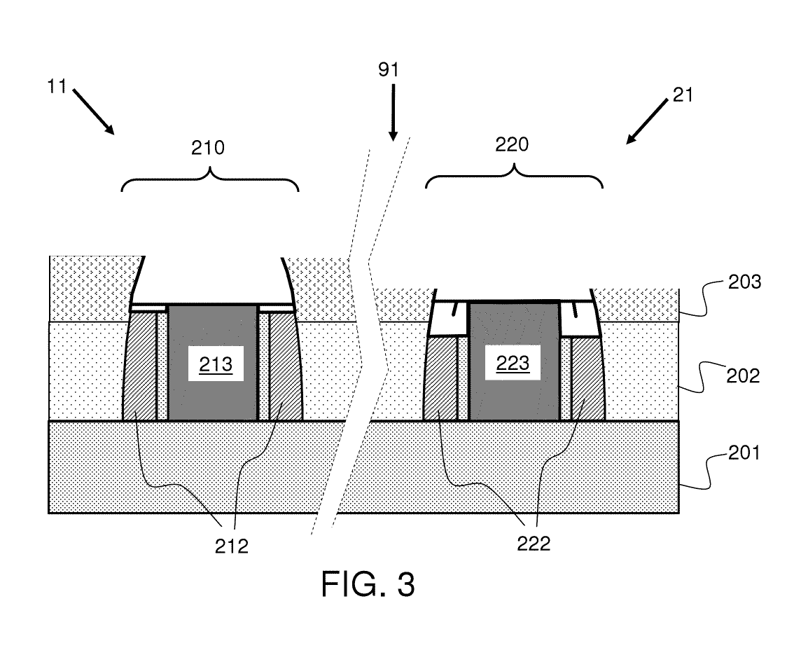

FIG. 3 is a demonstrative illustration of a method of forming transistors with replacement metal gate, following the step illustrated in FIG. 2, according to one embodiment of the present invention. More specifically, one embodiment of the method may include applying an isotropic etch back process to remove a substantially same amount, in terms of thickness, of dielectric layer 211 and 221 that was deposited in the preceding step. By applying this etch back process, embodiment of present invention enables the removal of most of the deposited dielectric layer 211 and 221 other than in areas of the divot, where a small fraction of the divot filling material of dielectric layer 211 and 221 were left to effectively fill up the divots that are around dummy gates of all of the transistors manufactured in the same substrate 201.

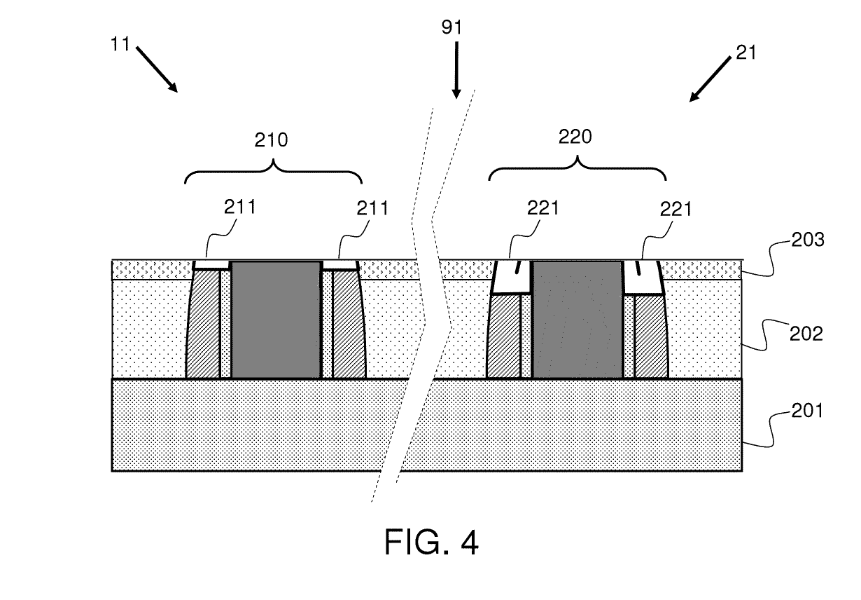

After the above isotropic etch back process, a CMP process is performed to polish portions of ILD layer 203 that are above the top surface of dummy gates 213 and 223 as being demonstratively illustrated in FIG. 4. The CMP process aligns the top surface of ILD layer 203 with the height of dummy gates 213 and 223 as well as a combined height of sidewall spacers 212 and 222 with their divot filling materials 211 and 221 on top thereof. As is clear in FIG. 4, height of dummy gates 213 and 223 were kept the same irrespective to their having different incoming nitride cap thicknesses.

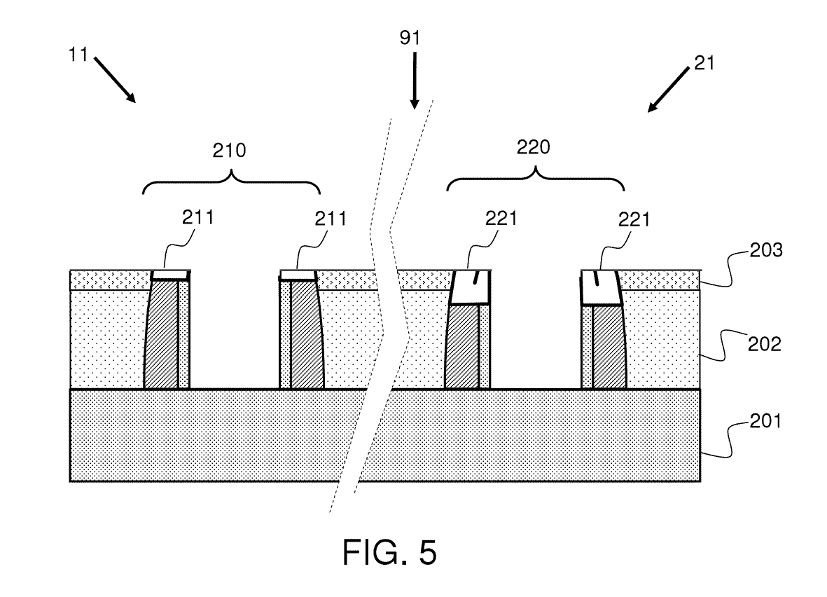

FIG. 5 is a demonstrative illustration of a method of forming transistors with replacement metal gate, following the step illustrated in FIG. 4, according to one embodiment of the present invention. More specifically, after removing dielectric layer 211 and 221 on top of the dummy gates 213 and 223 and polishing ILD layer 203 to create a planar top surface, dummy gates 213 and 223 may be removed selectively through a selective etching process such as a reactive-ion-etching (RIE) process. More specifically, the etching process may be selective to material of sidewall spacers 212 and 222, to the underneath substrate 201, and according to one embodiment selective to the remaining portion of deposited dielectric layer 211 and 221, also known as divot filling material, that remain above the sidewall spacers and that fill up divots created during the nitride cap layer removal in a previous step.

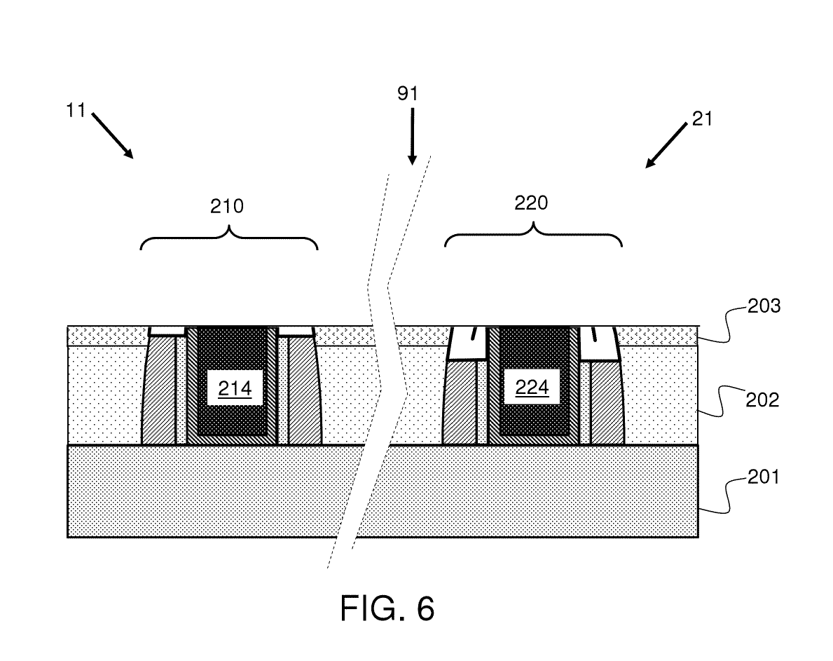

FIG. 6 is a demonstrative illustration of a method of forming transistors with replacement metal gate, following the step illustrated in FIG. 5, according to one embodiment of the present invention. More specifically, after the dummy gates 213 and 223 are removed, one or more work-function metal layers may be deposited into the openings left by the removal of dummy gates 213 and 223. The work-function metal layers line substrate 201, sidewalls of sidewall spacers 221 and 222, and line the divot filling material 211 and 221 that are directly above and on top of the sidewall spacers. Working metal gate material, such as aluminum (Al), copper (Cu), or tungsten (W), may subsequently be deposited into the remaining of the openings to create metal gates 214 and 224. The deposition may be followed by a planarization process to remove any excess metal gate material that may be deposited in areas around the metal gates 214 and 224 and above the metal gates 214 and 224.

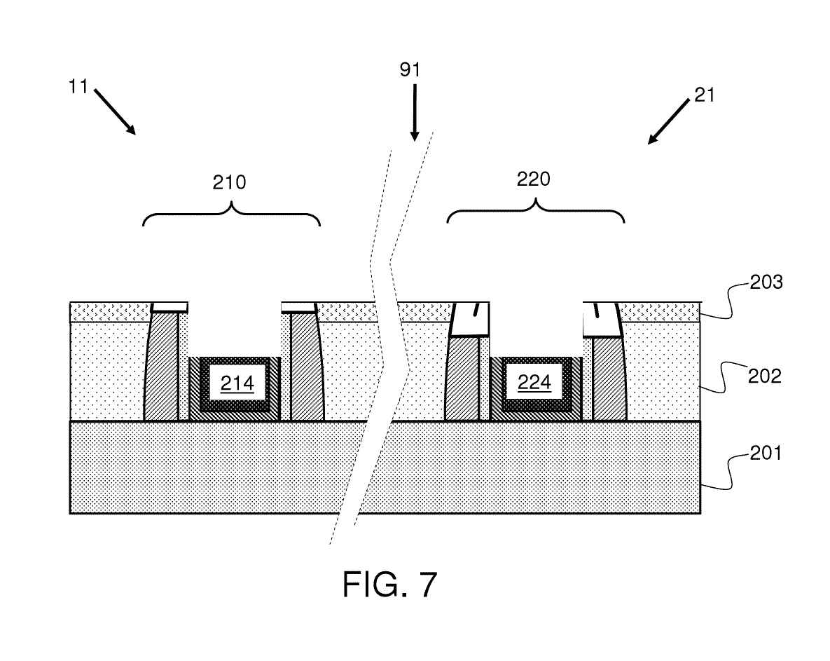

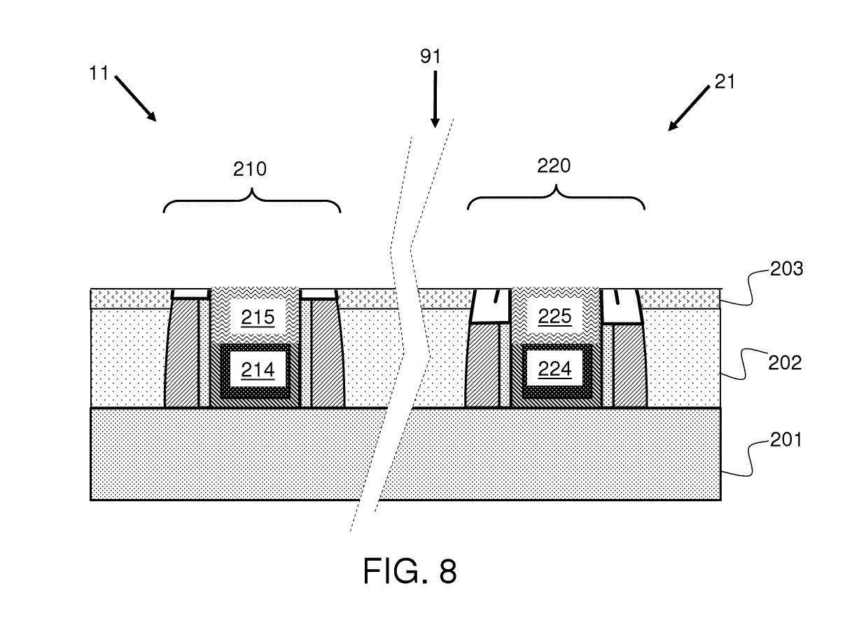

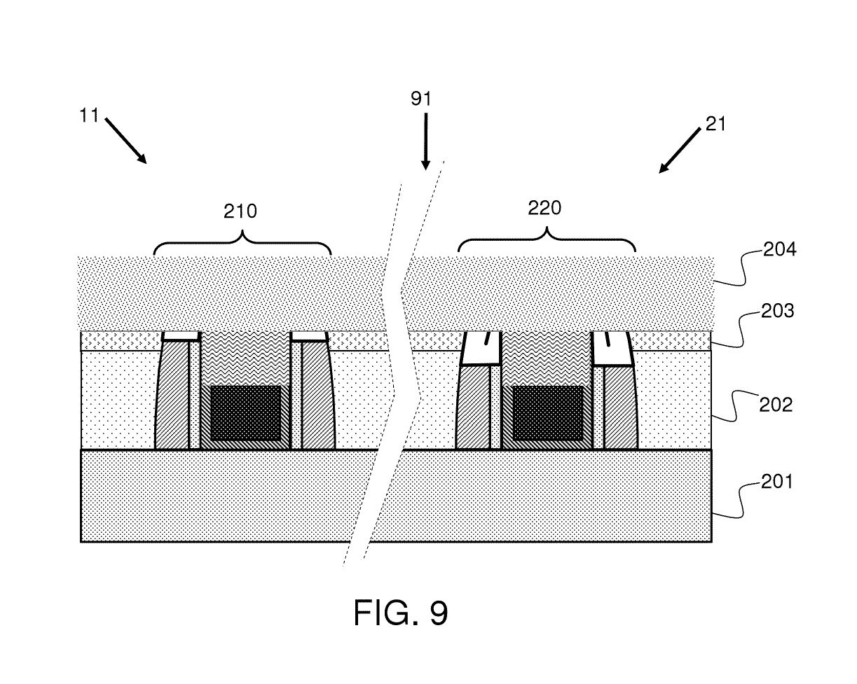

FIG. 7 is a demonstrative illustration of a method of forming transistors with replacement metal gate, following the step illustrated in FIG. 6, according to one embodiment of the present invention. In one embodiment where self-aligned-contact (SAC) to the source and/or drain of transistor is required, a new nitride cap may be formed on top of the high-k metal gate to isolate the gate from shorting to the source/drain. For example, in order to form nitride caps on top of the gates, high-k metal gates 214 and 224 may be recessed through, for example, a wet selective etch process to a level below the top surface of dielectric ILD layer 203 as being illustrated in FIG. 7. Next, a silicon-nitride (SiN) layer may be blanket deposited on top of recessed gate areas as well as on top of ILD layer 203. The deposition of SiN is then followed by a CMP process to remove SiN that are deposited on top of ILD layer 203 as well as excess SiN material that are above the level of ILD layer 203. As a result, SiN cap layers 215 and 225 may be formed on top of high-k metal gates 214 and 224, as being demonstratively illustrated in FIG. 8. Following the formation of nitride cap layers 215 and 225, ILD layer 204 of SiO2, for example, may be formed on top of SiN cap layers 215 and 225, divot filling material 211 and 221, and ILD layer 203 as being demonstratively illustrated in FIG. 9.

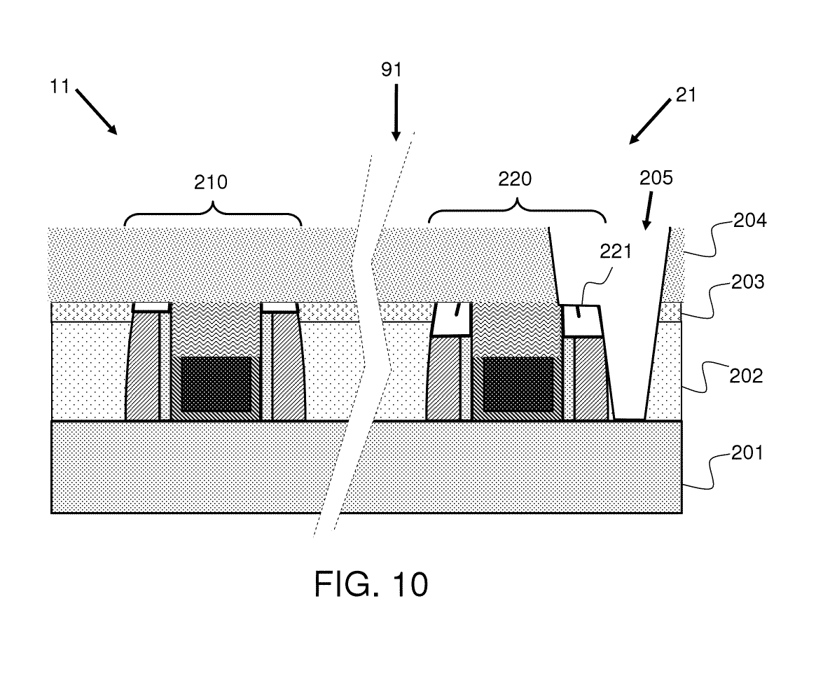

FIG. 10 is a demonstrative illustration of a method of forming transistors with replacement metal gate, following the step illustrated in FIG. 9, according to one embodiment of the present invention. More specifically, contact etch may be performed to create opening 205 inside ILD layer 204, ILD layer 203 underneath thereof, and dielectric layer 202. The contact etch process may be made selectively to divot filling material 221 such as silicon-nitride (SiN) or hafnium-oxide (HfO₂), and in situations where the divot filling material is HfO₂, the HfO₂ divot filling material may be able to provide better etch selectivity than underneath spacer material of typically SiN. Compared with a conventional etching process which may result in a corner loss of as big as 25 nm, with the help of HfO₂ divot filling material at the corner of sidewall spacers, corner loss may be greatly reduced which in turn help reduce the chance of contact to gate short. Conductive material may subsequently be used to fill opening 205 to form self-aligned-contact to source/drain of transistor 220.

While the invention has been described in terms of exemplary embodiments, those skilled in the art will recognize that the invention can be practiced with modifications and in the spirit and scope of the appended claims.

1. A method comprising:
forming a plurality of transistor structures on a semiconductor substrate, said plurality of transistor structures having a plurality of dummy gates; each dummy gate being surrounded by sidewall spacers of a height less than that of said dummy gate; said dummy gate and sidewall spacers being embedded inside one or more dielectric layers; said height of said sidewall spacers being different for different transistor structures resulting in divots of different depths for different transistor structures, at between said dummy gate and said one or more dielectric layers above said sidewall spacers;
depositing a conformal dielectric layer on top of said dummy gates; inside said divots of said plurality of transistor structures; and on top of said one or more dielectric layers having a height higher than a top surface of said dummy gates, said conformal dielectric layer having a thickness of at least half of a width of said divots and having a thickness on top of said dummy gates that is same as a thickness on top of said one or more dielectric layers;
removing a portion of said conformal dielectric layer that is on top of said dummy gates to expose said dummy gates of said plurality of transistor structures; and
replacing said dummy gates of said plurality of transistor structures with a plurality of high-k metal gates.

2. The method of claim 1, wherein removing said portion of said conformal dielectric layer on top of said dummy gates comprises applying an isotropic etch-back process to remove said portion of said conformal dielectric layer; said isotropic etch-back process leaving intact portions of said conformal dielectric layer that are deposited inside said divots.

3. The method of claim 2, further comprising, after removing said portion of said conformal dielectric layer that is on top of said dummy gates, polishing said one or more dielectric layers by a chemical-mechanic-polishing (CMP) process to create a top surface that is co-planar with respective top surfaces of said dummy gates of said plurality of transistor structures.

4. The method of claim 3, wherein replacing said dummy gates with said plurality of high-k metal gates comprises:
selectively removing said dummy gates of said plurality of transistor structures to expose said semiconductor substrate underneath thereof and said sidewall spacers;
lining said semiconductor substrate and said sidewall spacers with one or more work-function metal layers; and
depositing a conductive material on top of said one or more work-function metal layers to form said plurality of high-k metal gates.

5. The method of claim 4, further comprising creating recesses in said plurality of high-k metal gates and filling said recesses with an insulating material.

6. The method of claim 5, further comprising:
creating a contact opening inside said one or more dielectric layers through a selective etching process, said selective etching process being selective to said portions of conformal dielectric layer left inside said divots, said contact opening being self aligned to said sidewall spacers; and
filling said contact opening with a conductive material to form a source/drain contact.

7. The method of claim 1, wherein depositing said conformal dielectric layer inside said divots of said plurality of transistor structures comprises depositing a hafnium-oxide or a silicon-nitride material inside said divots above their respective sidewall spacers.

8. A method comprising:
forming a first and a second dummy gate structure on a common substrate, said first and second dummy gate structures having respectively a first and a second dummy gate of a substantially same height, said first and second dummy gates being surrounded respectively by a first set and a second set of sidewall spacers of different heights that are less than said substantially same height of their respective dummy gates resulting in divots of different depths around corners of their respective dummy gates;
depositing a conformal dielectric layer on top of said first and second dummy gates and inside said divots around said corners of said first and second dummy gates, said conformal dielectric layer having a thickness of at least half of a width of said divots;
removing portions of said conformal dielectric layer to expose said first and second dummy gates underneath thereof; and
replacing said first and second dummy gates with a first and a second high-k metal gates,
wherein removing said portions of said conformal dielectric layer comprises applying an isotropic etch-back process to remove said portions of said conformal dielectric layer while leaving rest of said conformal dielectric layer inside said divots.

9. (canceled)

10. The method of claim 8, wherein said first and second dummy gates and said first and second set of sidewall spacers are embedded inside one or more dielectric layers, further comprising polishing said one or more dielectric layers by a chemical-mechanic-polishing (CMP) process to create a top surface that is co-planar with top surfaces of said first and second dummy gates.

11. The method of claim 10, wherein replacing said first and second dummy gates comprises:
selectively removing said first and second dummy gates to expose said common substrate underneath thereof and said first and second set of sidewall spacers;
lining said common substrate and said sidewall spacers with one or more work-function metal layers; and
depositing a conductive material on top of said one or more work-function metal layers to form said first and second high-k metal gates.

12. The method of claim 11, further comprising creating recesses in said first and second high-k metal gates and filling said recesses with a nitride cap layer.

13. The method of claim 12, further comprising:
creating at least one contact opening inside said one or more dielectric layers through a selective etching process, said selective etching process being selective to said rest of said conformal dielectric layer inside said divots, said contact opening being self aligned to said first and second set of sidewall spacers; and
filling said contact opening with a conductive material to form a source/drain contact.

14. The method of claim 8, wherein depositing said conformal dielectric layer inside said divots comprises depositing a hafnium-oxide material inside said divots around said corners of said first and second dummy gates above their respective sidewall spacers.

15. A method comprising:
forming a first and a second gate structure on a same substrate, said first and second gate structures having respectively a first and a second dummy gate of a substantially same height and being covered by a first and a second hard mask of different thicknesses;
removing said first and second hard masks from said first and second dummy gates, said removing etches top portions of a first and a second set of sidewall spacers that are adjacent to said first and second dummy gates respectively and are embedded inside one or more dielectric layers, thereby causing divots of different depths above said first and second set of sidewall spacers surrounded by said one or more dielectric layers;
depositing a conformal dielectric layer on top of said first and second dummy gates; inside said divots; and on top of said one or more dielectric layers having a height higher than top surfaces of said first and second dummy gates, said conformal dielectric layer being sufficiently thick to fill up said divots and having a thickness on top of said first and second dummy gates same as a thickness on top of said one or more dielectric layers;
removing portions of said conformal dielectric layer to expose said first and second dummy gates underneath thereof; and
replacing said first and second dummy gates with a first and a second high-k metal gates.

16. The method of claim 15, wherein removing said portions of said conformal dielectric layer comprises isotropically etching a first portion of said conformal dielectric layer on top of said first and second dummy gates without affecting a second portion of said conformal dielectric layer that is deposited inside said divots.

17. The method of claim 16, further comprising planarizing said one or more dielectric layers surrounding said first and second gate structures using said first and second dummy gates as etch-stop.

18. The method of claim 17, wherein replacing said first and second dummy gates comprises:
selectively removing said first and second dummy gates to expose said substrate underneath thereof and said first and second set of sidewall spacers, thereby creating gate openings; and
filling gate openings with work-function metal and conductive material to form said first and second high-k metal gates.

19. The method of claim 18, further comprising creating recesses in said first and second high-k metal gates and filling said recesses with a nitride cap layer.

20. The method of claim 15, wherein depositing said conformal dielectric layer inside said divots comprises depositing a hafnium-oxide material inside said divots around said corners of said first and second dummy gates above their respective first and second set of sidewall spacers.
